(19) United States
(12) Patent Application Publication
(10) Pub. No.: US 2025/0040122 A1
(43) Pub. Date: Jan. 30, 2025

(54) SEMICONDUCTOR DEVICE

(71) Applicant: Samsung Electronics Co., Ltd., Suwon-si (KR)

(72) Inventors: Kyoo Ho JUNG, Suwon-si (KR); Ye Seul LEE, Suwon-si (KR); Jong Yeong MIN, Suwon-si (KR); Joon Suk PARK, Suwon-si (KR); Ji Ye BAEK, Suwon-si (KR); Jin Wook LEE, Suwon-si (KR)

(73) Assignee: Samsung Electronics Co., Ltd., Suwon-si (KR)

(21) Appl. No.: 18/442,228

(22) Filed: Feb. 15, 2024

(30) Foreign Application Priority Data
Jul. 28, 2023 (KR) 10-2023-0099008

(51) Int. Cl. H10B 12/00

(52) U.S. Cl. CPC H10B 12/315; H10B 12/033

(57) ABSTRACT

A semiconductor device includes a landing pad on a substrate; a lower electrode extending in a vertical direction on the landing pad, the lower electrode connected to the landing pad; a capacitor dielectric layer on the lower electrode; a doping layer between the lower electrode and the capacitor dielectric layer, the doping layer being in contact with each of the lower electrode and the capacitor dielectric layer, the doping layer is doped with first to third materials, the first material having a trivalent atom valence electron, the second material having a tetravalent atom valence electron, and the third material having a pentavalent atom valence electron; and an upper electrode on the capacitor dielectric layer.

### CROSS-REFERENCE TO RELATED APPLICATION

This application claims priority from Korean Patent Application No. 10-2023-0099008 filed on Jul. 28, 2023 in the Korean Intellectual Property Office and all the benefits accruing therefrom under 35 U.S.C. 119, the contents of which in its entirety are herein incorporated by reference.

### BACKGROUND

The present disclosure relates to a semiconductor device.

A Buried Channel Array Transistor (BCAT) may include a gate electrode buried in a trench to overcome a short channel effect of a DRAM structure.

As semiconductor devices become increasingly highly integrated, individual circuit patterns are becoming finer to implement more semiconductor devices in a same region. That is, design rules for components of a semiconductor device are decreasing. As DRAM devices are also integrated, the amount of charge capable of being stored in a capacitor is steadily decreasing. Therefore, studies for increasing the amount of charge stored in a capacitor and attenuating leakage characteristics are ongoing.

### SUMMARY

Example embodiments of the inventive concepts provide a semiconductor device in which a doping layer doped with all of a first material having a trivalent atom valence electron, a second material with a tetravalent atom valence electron, and a third material having a pentavalent atom valence electron is formed on a surface of a lower electrode to increase its capacitance, reduce its electric bridge defect and improve distribution of the third material.

Example embodiments of the inventive concepts provide a semiconductor device that includes a landing pad on a substrate; a lower electrode extending in a vertical direction on the landing pad, the lower electrode connected to the landing pad; a capacitor dielectric layer on the lower electrode; a doping layer between the lower electrode and the capacitor dielectric layer, the doping layer in contact with each of the lower electrode and the capacitor dielectric layer, the doping layer doped with first to third materials, the first material having a trivalent atom valence electron, the second material having a tetravalent atom valence electron, and the third material having a pentavalent atom valence electron; and an upper electrode on the capacitor dielectric layer.

Example embodiments of the inventive concepts further provide a semiconductor device that includes a landing pad on a substrate; a lower electrode extending in a vertical direction on the landing pad, the lower electrode connected to the landing pad; a first supporter pattern on at least one side of the lower electrode, the first supporter pattern in contact with sidewalls of the lower electrode; a second supporter pattern on at least one side of the lower electrode, the second supporter pattern in contact with the sidewalls of the lower electrode, the second supporter pattern spaced apart from the first supporter pattern in the vertical direction; a capacitor dielectric layer on the lower electrode and the second supporter pattern; and a doping layer between the lower electrode and the capacitor dielectric layer, the doping layer in contact with each of the lower electrode and the capacitor dielectric layer, the doping layer doped with first to third materials, the first material having a trivalent atom valence electron, the second material having a tetravalent atom valence electron, and the third material having a pentavalent atom valence electron. At least a portion of the doping layer is in contact with sidewalls of the second supporter pattern on an upper surface of the lower electrode.

Example embodiments of the inventive concepts still further provide a semiconductor device that includes a landing pad on a substrate; a lower electrode extending in a vertical direction on the landing pad, the lower electrode connected to the landing pad; a first supporter pattern on at least one side of the lower electrode, the first supporter pattern in contact with sidewalls of the lower electrode; a second supporter pattern on at least one side of the lower electrode, the second supporter pattern in contact with the sidewalls of the lower electrode, the second supporter pattern spaced apart from the first supporter pattern in the vertical direction; a capacitor dielectric layer on the lower electrode and the second supporter pattern; a doping layer between the lower electrode and the capacitor dielectric layer and between an upper surface of the second supporter pattern and the capacitor dielectric layer, the doping layer in contact with each of the lower electrode, the capacitor dielectric layer and the upper surface of the second supporter pattern, the doping layer doped with first to third materials, the first material having a trivalent atom valence electron, the second material having a tetravalent atom valence electron, and the third material having a pentavalent atom valence electron; and an upper electrode on the capacitor dielectric layer. At least a portion of the doping layer is in contact with sidewalls of the second supporter pattern on an upper surface of the lower electrode. An atomic percent of the first material doped in the doping layer is smaller than an atomic percent of the third material doped in the doping layer. The doping layer on the upper surface of the lower electrode has first thickness in the vertical direction, the doping layer on the upper surface of the second supporter pattern has a second thickness in the vertical direction, and the first thickness is greater than the second thickness.

The objects of the inventive concepts are not limited to those mentioned above and additional objects of the inventive concepts, which are not mentioned herein, will be clearly understood by those skilled in the art from the following description of the inventive concepts.

### BRIEF DESCRIPTION OF THE DRAWINGS

The above and other aspects and features of the inventive concepts will become more apparent by describing in detail some example embodiments thereof with reference to the attached drawings, in which:

FIG. 1 is a view illustrating a semiconductor device according to some example embodiments of the inventive concepts;

FIG. 2 is an enlarged view illustrating a region R1 of FIG. 1;

FIGS. 3, 4, 5, 6, 7, 8 and 9 are views illustrating intermediate steps descriptive of a method of fabricating a semiconductor device shown in FIG. 1;

FIG. 10 is a view illustrating a semiconductor device according to some other example embodiments of the inventive concepts;

FIG. 11 is an enlarged view illustrating a region R2 shown in FIG. 10;

FIGS. 12, 13 and 14 are views illustrating intermediate steps descriptive of a method of fabricating a semiconductor device shown in FIG. 10;

FIG. 15 is a view illustrating a semiconductor device according to some other example embodiments of the inventive concepts;

FIG. 16 is a view illustrating a semiconductor device according to some other example embodiments of the inventive concepts;

FIG. 17 is a view illustrating a semiconductor device according to some other example embodiments of the inventive concepts;

FIG. 18 is a layout view illustrating a semiconductor device according to some other example embodiments of the inventive concepts;

FIG. 19 is a perspective view illustrating a semiconductor device according to some other example embodiments of the inventive concepts;

FIG. 20 is a cross-sectional view taken along lines F-F and G-G of FIG. 18;

FIG. 21 is a layout view illustrating a semiconductor device according to some other example embodiments of the inventive concepts; and

FIG. 22 is a perspective view illustrating a semiconductor device according to some other example embodiments of the inventive concepts.

### DETAILED DESCRIPTION

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

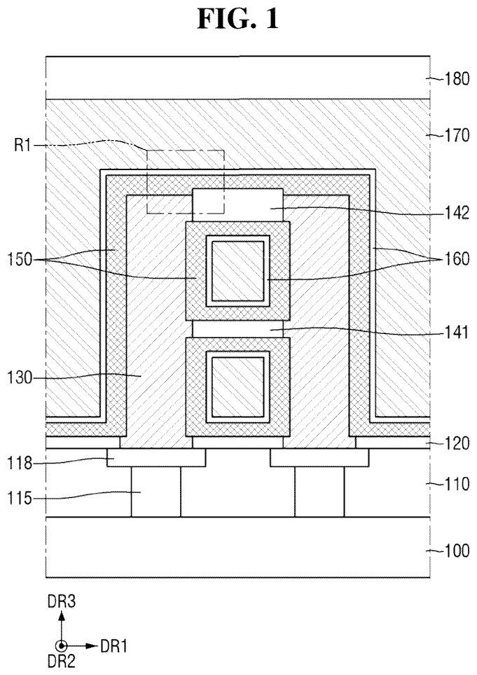

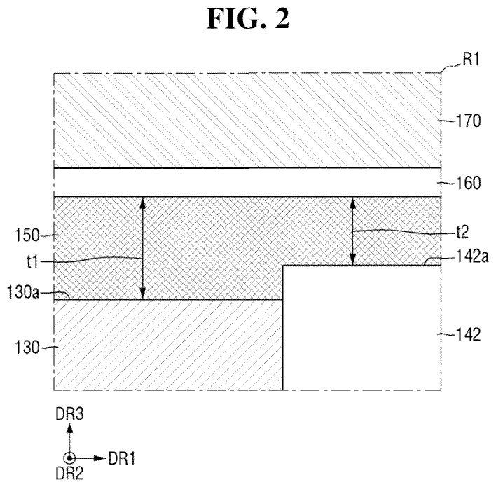

Hereinafter, a semiconductor device according to some example embodiments of the inventive concepts will be described with reference to FIGS. 1 and 2.

FIG. 1 is a view illustrating a semiconductor device according to some example embodiments of the inventive concepts. FIG. 2 is an enlarged view illustrating a region R1 of FIG. 1.

Referring to FIGS. 1 and 2, the semiconductor device according to some example embodiments of the inventive concepts includes a substrate 100, a first interlayer insulating layer 110, a storage contact 115, a landing pad 118, an etch stop layer 120, a lower electrode 130, a first supporter pattern 141, a second supporter pattern 142, a doping layer 150, a capacitor dielectric layer 160, an upper electrode 170, and a second interlayer insulating layer 180.

The substrate 100 may be bulk silicon or silicon-on-insulator (SOI). Alternatively, the substrate 100 may include a silicon substrate, or may include other materials such as silicon germanium, silicon germanium on insulator (SGOI), indium antimonide, lead telluride compound, indium arsenide, indium phosphide, gallium arsenide or gallium antimonide, but is not limited thereto. The following description will be based on that the substrate 100 is a silicon substrate.

Although not shown, a gate electrode used as a word line may be disposed inside the substrate 100. A unit active region and a device isolation region may be formed in the substrate 100. For example, two transistors may be formed in one unit active region.

Hereinafter, each of a first horizontal direction DR1 and a second horizontal direction DR2 may be defined as a direction parallel with an upper surface of the substrate 100. A vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The first interlayer insulating layer 110 may be disposed on the substrate 100. The first interlayer insulating layer 110 may include at least one of, for example, silicon oxide, silicon nitride, silicon oxynitride, a low-k material or their combination. The storage contact 115 may be disposed inside the first interlayer insulating layer 110 on the substrate 100. The landing pad 118 may be disposed inside the first interlayer insulating layer 110 on the substrate 100. The landing pad 118 may be disposed on the storage contact 115. The landing pad 118 may be connected to the substrate 100 via the storage contact 115. The landing pad 118 may be electrically connected to a conductive region formed on the substrate 100 or in the substrate 100. Each of the storage contact 115 and the landing pad 118 may include a conductive material.

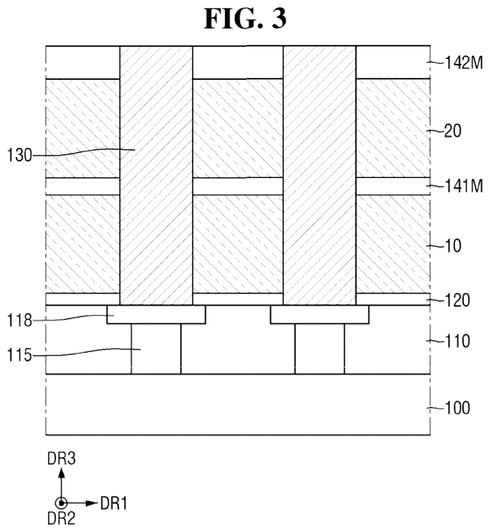

The etch stop layer 120 may be disposed on the first interlayer insulating layer 110. The etch stop layer 120 may surround a portion of sidewalls of the lower electrode 130 formed to be adjacent to an upper surface of the first interlayer insulating layer 110. The etch stop layer 120 may include a material having an etch selectivity with respect to a first mold layer (10 of FIG. 3) and a second mold layer (20 of FIG. 3), which include oxide. The etch stop layer 120 may include at least one of, for example, silicon nitride (SiN), silicon carbonitride (SiCN), silicon boron nitride (SiBN), silicon carbon oxide (SiCO), silicon oxynitride (SiON), silicon oxide (SiO) or silicon oxycarbonitride (SiOCN). For example, the silicon carbon oxide (SiCO) includes silicon (Si), carbon (C) and oxygen (O), but does not mean a ratio among silicon (Si), carbon (C) and oxygen (O).

A plurality of lower electrodes 130 may be disposed on the landing pad 118. Each of the plurality of lower electrodes 130 is connected to the landing pad 118. Each of the plurality of lower electrodes 130 may be extended lengthwise in the vertical direction DR3. For example, a length of the lower electrode 130 extended in the vertical direction DR3 is greater than that of the lower electrode 130 extended in the first horizontal direction DR1. Alternatively, the length of the lower electrode 130 extended in the vertical direction DR3 is greater than a width of the lower electrode 130 in the first horizontal direction DR1. For example, the lower electrode 130 may have a pillar shape. For example, a portion of a lower surface of the lower electrode 130 and a portion of sidewalls of a lower portion of the lower electrode 130 may be in contact with the etch stop layer 120.

The lower electrode 130 may include, for example, a conductive metal nitride (e.g., titanium nitride, tantalum nitride, niobium nitride or tungsten nitride), a metal (e.g., ruthenium, iridium, titanium or tantalum) and a conductive metal oxide (e.g., iridium oxide or niobium oxide), but the inventive concepts are not limited thereto.

The first supporter pattern 141 may be disposed on the etch stop layer 120. The first supporter pattern 141 may be spaced apart from the etch stop layer 120 in the vertical direction DR3. The first supporter pattern 141 may be disposed on at least one side of the lower electrode 130. The first supporter pattern 141 may be in contact with a portion of the sidewalls of the lower electrode 130. For example, the first supporter pattern 141 may connect the lower electrodes 130 adjacent to each other in the first horizontal direction DR1. Although two lower electrodes 130 are shown in FIG. 1 as being connected to each other by the first supporter pattern 141, this is for convenience of description and the inventive concepts are not limited thereto.

The second supporter pattern 142 may be disposed on the first supporter pattern 141. The second supporter pattern 142 may be spaced apart from the first supporter pattern 141 in the vertical direction DR3. The second supporter pattern 142 may be disposed on at least one side of the lower electrode 130. The second supporter pattern 142 may be in contact with a portion of the sidewalls of the lower electrode 130. For example, the second supporter pattern 142 may connect the lower electrodes 130 adjacent to each other in the first horizontal direction DR1. Although two lower electrodes 130 are shown in FIG. 1 as being connected to each other by the second supporter pattern 142, this is for convenience of description and the inventive concepts are not limited thereto. For example, an upper portion of the second supporter pattern 142 may be more protruded in the vertical direction DR3 than an upper surface 130a of the lower electrode 130. That is, an upper surface 142a of the second supporter pattern 142 may be formed to be higher than the upper surface 130a of the lower electrode 130.

For example, a thickness of the first supporter pattern 141 in the vertical direction DR3 may be smaller than that of the second supporter pattern 142 in the vertical direction DR3. In some other example embodiments, only one of the first supporter pattern 141 and the second supporter pattern 142 may be disposed on the sidewalls of the lower electrode 130. Also, in some other example embodiments, an additional supporter pattern may be disposed between the etch stop layer 120 and the first supporter pattern 141 or between the first supporter pattern 141 and the second supporter pattern 142. Each of the first supporter pattern 141 and the second supporter pattern 142 may include at least one of, for example, silicon nitride (SiN), silicon carbonitride (SiCN), silicon boron nitride (SiBN), silicon carbon oxide (SiCO), silicon oxynitride (SiON), silicon oxide (SiO) or silicon oxycarbonitride (SiOCN).

The doping layer 150 may be disposed on the sidewalls and the upper surface 130a of the lower electrode 130. The doping layer 150 may be disposed on a lower surface and an upper surface of the first supporter pattern 141. The doping layer 150 may be disposed on a lower surface and the upper surface 142a of the second supporter pattern 142. The doping layer 150 may be disposed on an upper surface of the etch stop layer 120. For example, the doping layer 150 may be in contact with each of the lower electrode 130, the first supporter pattern 141, the second supporter pattern 142 and the etch stop layer 120.

For example, at least a portion of the doping layer 150 may be in contact with sidewalls of the second supporter pattern 142 on the upper surface 130a of the lower electrode 130. For example, at least a portion of the doping layer 150 may overlap the lower electrode 130 in the vertical direction DR3 between the etch stop layer 120 and the first supporter pattern 141. For example, at least a portion of the doping layer 150 may overlap the lower electrode 130 in the vertical direction DR3 between the first supporter pattern 141 and the second supporter pattern 142.

For example, a first thickness t1 of the doping layer 150 in the vertical direction DR3, which is disposed on the upper surface 130a of the lower electrode 130, may be greater than a second thickness t2 of the doping layer 150 in the vertical direction DR3, which is disposed on the upper surface of the second supporter pattern 142. For example, the first thickness t1 of the doping layer 150 in the vertical direction DR3, which is disposed on the upper surface 130a of the lower electrode 130, may be greater than a thickness of the doping layer 150 in the vertical direction DR3, which is disposed on the upper surface of the etch stop layer 120.

The doping layer 150 may include a metal oxide as a base material. For example, the doping layer 150 may include titanium oxide, tantalum oxide, iridium oxide, niobium oxide or ruthenium oxide as a base material. The doping layer 150 may include a first material, a second material and a third material, which are doped in the base material. The first material, the second material and the third material may be materials different from one another.

For example, the first material may be a material having a trivalent atom valence electron. The first material may include at least one of, for example, aluminum (Al), gallium (Ga), indium (In), yttrium (Y), scandium (Sc) or lanthanum (La). The second material may be a material having a tetravalent atom valence electron. The second material may include at least one of, for example, zirconium (Zr), hafnium (Hf), silicon (Si), germanium (Ge) or tin (Sn). The third material may be a material having a pentavalent atom valence electron. The third material may include at least one of, for example, niobium (Nb), tantalum (Ta), vanadium (V), nitrogen (N), phosphorus (P), arsenic (As) or antimony (Sb).

For example, the third material having a pentavalent atom valence electron may increase capacitance of the doping layer 150. The second material having a tetravalent atom valence electron may improve distribution of the third material having a pentavalent atom valence electron, which is doped in the doped layer 150. The first material having a trivalent atom valence electron may reduce an electric bridge defect of the doping layer 150.

For example, an atomic percent of the first material doped in the doping layer 150 may be about 0.1 at % to 10 at %. An atomic percent of the second material doped in the doping layer 150 may be about 1 at % to 30 at %. An atomic percent of the third material doped in the doping layer 150 may be about 0.1 at % to 10 at %. For example, the atomic percent of the first material doped in the doping layer 150 may be smaller than the atomic percent of the third material doped in the doping layer 150.

The capacitor dielectric layer 160 may be disposed on the doping layer 150. The capacitor dielectric layer 160 may be disposed along a surface of the doping layer 150. The capacitor dielectric layer 160 may be in contact with the doping layer 150. For example, the doping layer 150 may be disposed between the lower electrode 130 and the capacitor dielectric layer 160. The doping layer 150 may be disposed between the first supporter pattern 141 and the capacitor dielectric layer 160. The doping layer 150 may be disposed between the second supporter pattern 142 and the capacitor dielectric layer 160. The doping layer 150 may be disposed between the etch stop layer 120 and the capacitor dielectric layer 160. For example, the capacitor dielectric layer 160 may be formed to be conformal.

For example, the capacitor dielectric layer 160 is not disposed between the lower electrode 130 and the first supporter pattern 141. The capacitor dielectric layer 160 is not disposed between the lower electrode 130 and the second supporter pattern 142. The capacitor dielectric layer 160 is not disposed between the lower electrode 130 and the etch stop layer 120.

The capacitor dielectric layer 160 may include one of, for example, silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate and their combination, but the inventive concepts are not limited thereto. Although the capacitor dielectric layer 160 is shown in FIGS. 1 and 2 as a single layer, the inventive concepts are not limited thereto. In some other example embodiments, the capacitor dielectric layer 160 may be formed of multiple layers.

The upper electrode 170 may be disposed on the capacitor dielectric layer 160. The upper electrode 170 may be disposed to cover the sidewalls and the upper surface of the lower electrode 130. The upper electrode 170 may be disposed between the etch stop layer 120 and the first supporter pattern 141. The upper electrode 170 may be disposed between the first supporter pattern 141 and the second supporter pattern 142.

The upper electrode 170 may include, for example, a conductive metal nitride (e.g., titanium nitride, tantalum nitride, niobium nitride or tungsten nitride), a metal (e.g., ruthenium, iridium, titanium or tantalum) and a conductive metal oxide (e.g., iridium oxide or niobium oxide), but the inventive concepts are not limited thereto.

The second interlayer insulating layer 180 may be disposed on the upper electrode 170. The second interlayer insulating layer 180 may include at least one of, for example, silicon oxide, silicon nitride, silicon oxynitride, a low-k material or their combination.

In the semiconductor device according to some example embodiments of the inventive concepts, the doping layer 150 may be doped with a first material having a trivalent atom valence electron, a second material having a tetravalent atom valence electron and a third material having a pentavalent atom valence electron. For example, the third material having a pentavalent atom valence electron may increase capacitance of the doping layer 150. However, when a concentration of the third material having a pentavalent atom valence electron, which is doped in the doping layer 150, is increased to a critical concentration or more, a problem occurs in that the capacitance of the doping layer 150 is no longer increased and the third material having a pentavalent atom valence electron on the surface of the doping layer 150 is oxidized to act as a low dielectric.

In order to limit and/or prevent such problems, in the semiconductor device according to some example embodiments of the inventive concepts, the doping layer 150 may be doped with a second material having a tetravalent atom valence electron. For example, the second material having a tetravalent atom valence electron, which is doped in the doping layer 150, may improve distribution of the third material having a pentavalent atom valence electron, which is doped in the doping layer 150. Also, in the semiconductor device according to some example embodiments of the inventive concepts, the doping layer 150 may be doped with a first material having a trivalent atom valence electron. For example, the first material having a trivalent atom valence electron may reduce an electric bridge defect of the doping layer 150.

As a result, in the semiconductor device according to some example embodiments of the inventive concepts, the doping layer 150 may be doped with all of the first material having a trivalent atom valence electron, the second material having a tetravalent atom valence electron and the third material having a pentavalent atom valence electron, whereby capacitance of the doping layer 150 may be increased, distribution of the third material having a pentavalent atom valence electron, which is doped in the doping layer 150, may be improved, and the electric bridge defect of the doping layer 150 may be reduced.

Hereinafter, a method of fabricating a semiconductor device according to some other example embodiments of the inventive concepts will be described with reference to FIGS. 1 and 3 to 9.

FIGS. 3 to 9 are views illustrating intermediate steps to describe a method of fabricating a semiconductor device shown in FIG. 1.

Referring to FIG. 3, a storage contact 115 and a landing pad 118 may be formed in a first interlayer insulating layer 110 on a substrate 100. Then, an etch stop layer 120, a first mold layer 10, a first supporter material layer 141M, a second mold layer 20 and a second supporter material layer 142M may be sequentially formed on the first interlayer insulating layer 110.

Each of the first supporter material layer 141M and the second supporter material layer 142M may include at least one of silicon nitride (SiN), silicon carbonitride (SiCN), silicon boron nitride (SiBN), silicon carbon oxide (SiCO), silicon oxynitride (SiON), silicon oxide (SiO) or silicon oxycarbonitride (SiOCN). Each of the first mold layer 10 and the second mold layer 20 may include, for example, silicon oxide (SiO₂). Each of the first mold layer 10 and the second mold layer 20 may include, for example, a flowable oxide (FOX), a Tonen SilaZen (TOSZ), an undoped silica glass (USG), a Borosilica Glass (BSG), a Phosphosilica Glass (PSG), a BoroPhosphosilica Glass (BPSG), a Plasma Enhanced Tetra Ethyl Ortho Silicate (PE-TEOS), a Fluoride Silicate Glass (FSG) or their combination.

Subsequently, a plurality of lower electrodes 130 passing through each of the etch stop layer 120, the first mold layer 10, the first supporter material layer 141M, the second mold layer 20 and the second supporter material layer 142M in the vertical direction DR3 may be formed on the landing pad 118. Each of the plurality of lower electrodes 130 may be connected to the landing pad 118.

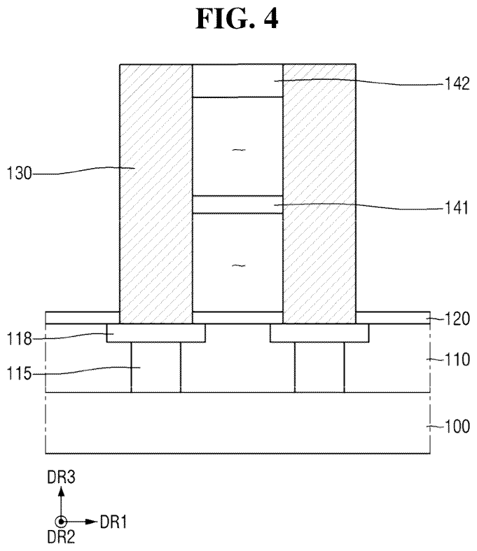

Referring to FIG. 4, a first supporter pattern 141 and a second supporter pattern 142, which connect adjacent lower electrodes 130, may be formed. Each of the first supporter pattern 141 and the second supporter pattern 142 may be in contact with a portion of sidewalls of the lower electrode 130.

For example, the second supporter pattern 142 may be formed by removing a portion of the second supporter material layer (142M of FIG. 3). The first supporter pattern 141 may be formed by removing a portion of the first supporter material layer (141M of FIG. 3). Then, the first mold layer (10 of FIG. 3) and the second mold layer (20 of FIG. 3) may be etched through a region in which each of the second supporter pattern 142 and the first supporter pattern 141 is not formed. The sidewalls of the lower electrode 130 may be exposed by etching the first mold layer (10 of FIG. 3) and the second mold layer (20 of FIG. 3). A space may be formed between the etch stop layer 120 and the first supporter pattern 141 and between the first supporter pattern 141 and the second supporter pattern 142.

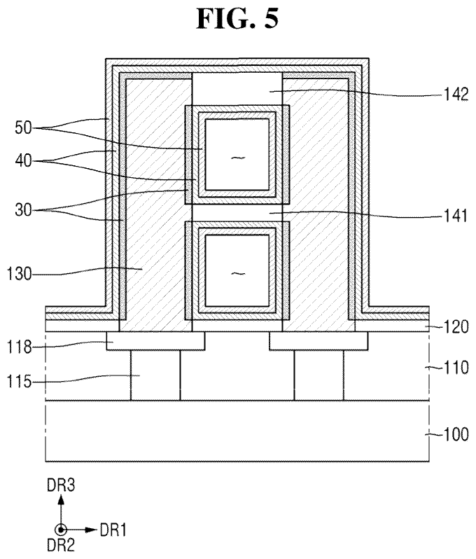

Referring to FIG. 5, the exposed portion of the lower electrode 130 may be oxidized to form a metal oxide layer 30. For example, the metal oxide layer 30 may be formed on the sidewalls and an upper surface of the lower electrode 130. For example, the metal oxide layer 30 may be formed on the exposed sidewall of the lower electrode 130 between the etch stop layer 120 and the first supporter pattern 141. The metal oxide layer 30 may be formed on the exposed sidewall of the lower electrode 130 between the first supporter pattern 141 and the second supporter pattern 142. For example, the metal oxide layer 30 may include titanium oxide, tantalum oxide, iridium oxide, niobium oxide or ruthenium oxide.

A first layer 40 may be formed on an upper surface of the etch stop layer 120, an exposed surface of the metal oxide layer 30, an exposed surface of the first supporter pattern 141 and an exposed surface of the second supporter pattern 142. For example, the first layer 40 may be formed to be conformal. The first layer 40 may be, for example, an oxide layer that includes a first material having a trivalent atom valence electron and a second material having a tetravalent atom valence electron. The second layer 50 may be formed on the first layer 40. For example, the second layer 50 may be formed to be conformal. The second layer 50 may be, for example, an oxide layer that includes a third material having a pentavalent atom valence electron.

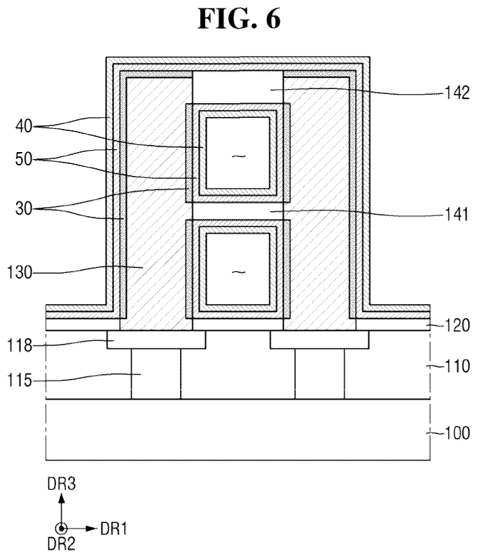

FIG. 6 is another fabricating process different from the fabricating process shown in FIG. 5. Referring to FIG. 6, after the metal oxide layer 30 is formed, the second layer 50 may be formed on the upper surface of the etch stop layer 120, the exposed surface of the metal oxide layer 30, the exposed surface of the first supporter pattern 141 and the exposed surface of the second supporter pattern 142. For example, the second layer 50 may be formed to be conformal. The second layer 50 may be, for example, an oxide layer that includes a third material having a pentavalent atom valence electron. Then, the first layer 40 may be formed on the second layer 50. For example, the first layer 40 may be formed to be conformal. The first layer 40 may be, for example, an oxide layer that includes a first material having a trivalent atom valence electron and a second material having a tetravalent atom valence electron.

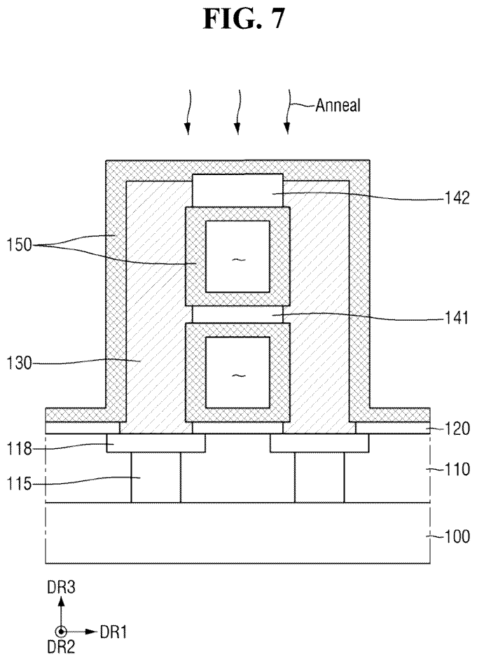

Referring to FIG. 7, an annealing process may be performed for the metal oxide layer (30 of FIGS. 5 and 6), the first layer (40 of FIGS. 5 and 6) and the second layer (50 of FIGS. 5 and 6). The metal oxide layer (30 of FIGS. 5 and 6), the first layer (40 of FIGS. 5 and 6) and the second layer (50 of FIGS. 5 and 6) may be converted into the doped layer 150 through the annealing process. The doping layer 150 may include a metal oxide as a base material. The doping layer 150 may include each of a first material having a doped trivalent atom valence electron, a second material having a doped tetravalent atom valence electron and a third material having a doped pentavalent atom valence electron.

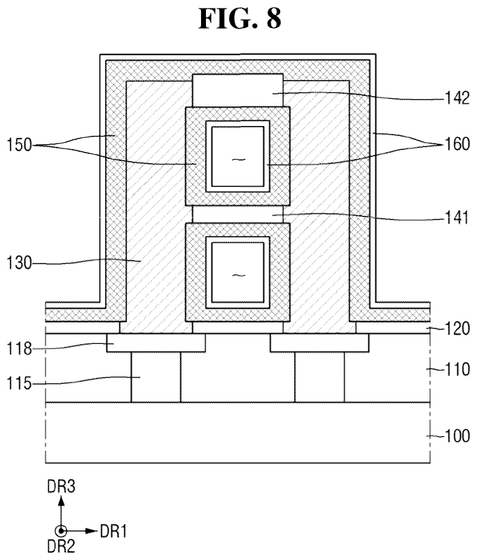

Referring to FIG. 8, a capacitor dielectric layer 160 may be formed on the doping layer 150. For example, the capacitor dielectric layer 160 may be formed along the exposed surface of the doped layer 150. For example, the capacitor dielectric layer 160 may be formed to be conformal.

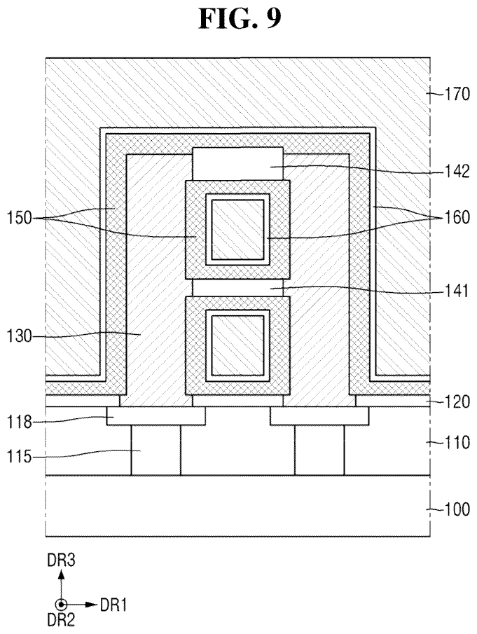

Referring to FIG. 9, an upper electrode 170 may be formed on the capacitor dielectric layer 160. The upper electrode 170 may be formed to cover the sidewalls and the upper surface of the lower electrode 130.

Referring to FIG. 1, a second interlayer insulating layer 180 may be formed on the upper electrode 170. For example, a plurality of wiring layers may be formed inside the second interlayer insulating layer 180. Through this fabricating process, the semiconductor device shown in FIGS. 1 and 2 may be fabricated.

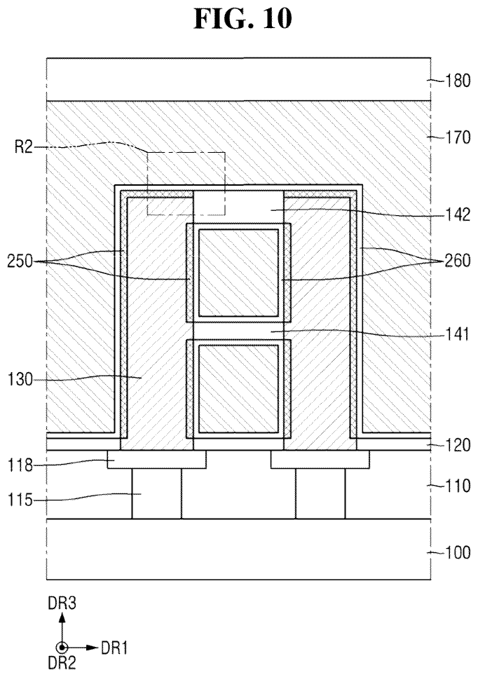

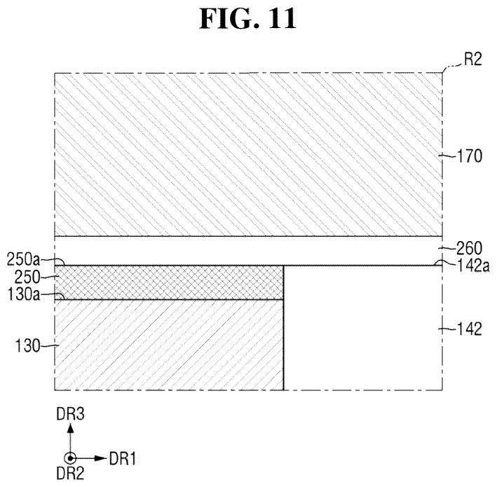

Hereinafter, a semiconductor device according to some other example embodiments of the inventive concepts will be described with reference to FIGS. 10 and 11. The following description will be based on differences from the semiconductor device shown in FIGS. 1 and 2.

FIG. 10 is a view illustrating a semiconductor device according to some other example embodiments of the inventive concepts. FIG. 11 is an enlarged view illustrating a region R2 shown in FIG. 10.

Referring to FIGS. 10 and 11, in the semiconductor device according to some other example embodiments of the inventive concepts, a capacitor dielectric layer 260 may be in contact with a surface of an etch stop layer 120, a surface of a first supporter pattern 141 and a surface of a second supporter pattern 142.

For example, a doping layer 250 is not disposed on each of an upper surface of the etch stop layer 120, a lower surface and an upper surface of the first supporter pattern 141 and a lower surface and an upper surface 142a of the second supporter pattern 142. The capacitor dielectric layer 260 may be in contact with each of the upper surface of the etch stop layer 120, the lower surface and the upper surface of the first supporter pattern 141 and the lower surface and the upper surface 142a of the second supporter pattern 142. For example, an uppermost surface 250a of the doping layer 250 may be formed on the same plane as the upper surface 142a of the second supporter pattern 142.

Hereinafter, a method of fabricating a semiconductor device according to some other example embodiments of the inventive concepts will be described with reference to FIGS. 10 and 12 to 14. The following description will be based on differences from the method of fabricating a semiconductor device shown in FIGS. 3 to 9.

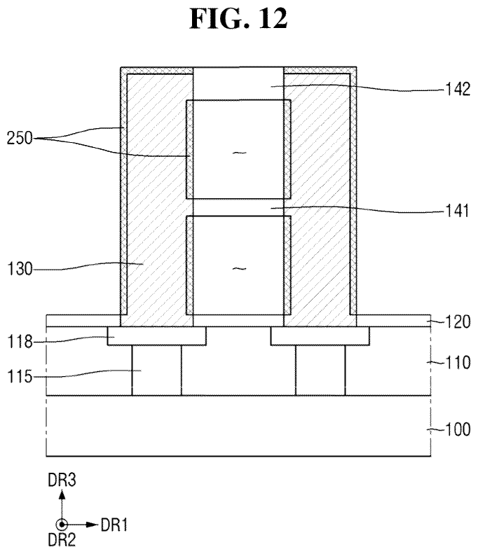

FIGS. 12 to 14 are views illustrating intermediate steps to describe a method of fabricating a semiconductor device shown in FIG. 10.

Referring to FIG. 12, after the fabricating process shown in FIGS. 3 to 7 is performed, a portion of the surface of the exposed doping layer (150 of FIG. 7) may be etched. After the etching process for the doping layer (150 of FIG. 7) is performed, the remaining doped layer (150 of FIG. 7) may be defined as the doping layer 250 shown in FIG. 12. After the etching process for the doping layer (150 of FIG. 7) is performed, each of the upper surface of the etch stop layer 120, the lower surface and the upper surface of the first supporter pattern 141 and the lower surface and the upper surface of the second supporter pattern 142 may be exposed. For example, an uppermost surface of the doping layer 250 may be formed on the same plane as the upper surface of the second supporter pattern 142, but the inventive concepts are not limited thereto.

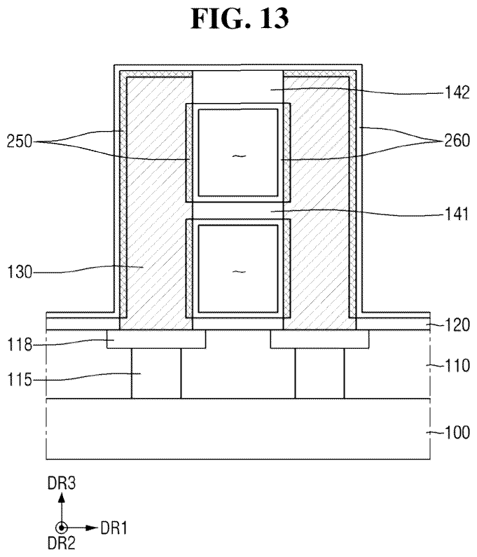

Referring to FIG. 13, a capacitor dielectric layer 260 may be formed on the upper surface of the etch stop layer 120, a surface of the doping layer 250, the lower surface and the upper surface of the first supporter pattern 141 and the lower surface and the upper surface of the second supporter pattern 142. The capacitor dielectric layer 260 may be in contact with each of the upper surface of the etch stop layer 120, the surface of the doping layer 250, the lower surface and the upper surface of the first supporter pattern 141 and the lower surface and the upper surface of the second supporter pattern 142. For example, the capacitor dielectric layer 260 may be formed to be conformal.

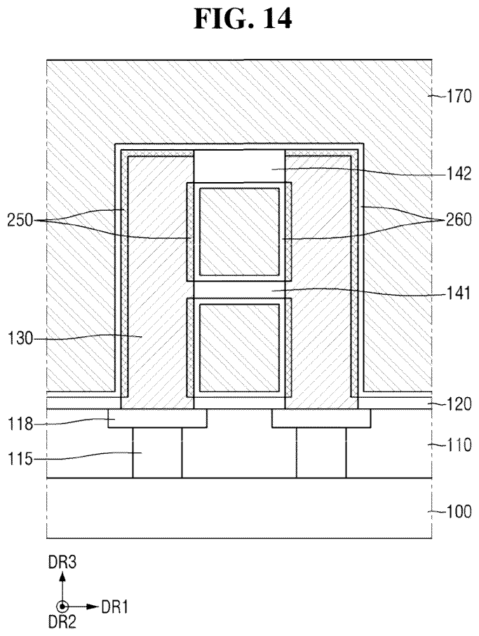

Referring to FIG. 14, an upper electrode 170 may be formed on the capacitor dielectric layer 260. The upper electrode 170 may be formed to cover the sidewalls and the upper surface of the lower electrode 130.

Referring to FIG. 10, a second interlayer insulating layer 180 may be formed on the upper electrode 170. For example, a plurality of wiring layers may be formed inside the second interlayer insulating layer 180. Through this fabricating process, the semiconductor device shown in FIGS. 10 and 11 may be fabricated.

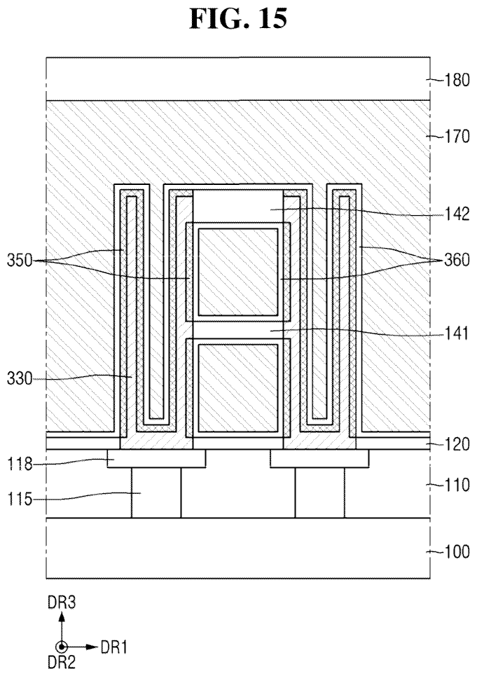

Hereinafter, a semiconductor device according to some other example embodiments of the inventive concepts will be described with reference to FIG. 15. The following description will be based on differences from the semiconductor device shown in FIGS. 1 and 2.

FIG. 15 is a view illustrating a semiconductor device according to some other example embodiments of the inventive concepts.

Referring to FIG. 15, in a semiconductor device according to some other example embodiments of the inventive concepts, a lower electrode 330 may have a cylinder shape. For example, the lower electrode 330 may have sidewalls and a bottom surface, and may have a hollow cylindrical shape. The sidewalls of the lower electrode 330 may be extended in the vertical direction DR3.

For example, a doping layer 350 may be disposed on the lower electrode 330. The doping layer 350 is not disposed between the lower electrode 330 and the etch stop layer 120, between the lower electrode 330 and the first supporter pattern 141 and between the lower electrode 330 and the second supporter pattern 142. A capacitor dielectric layer 360 may be disposed on the doping layer 350. The capacitor dielectric layer 360 may be disposed along the upper surface of the etch stop layer 120, the lower surface and the upper surface of the first supporter pattern 141 and the lower surface and the upper surface of the second supporter pattern 142.

The upper electrode 170 may be disposed on the capacitor dielectric layer 360. A portion of the upper electrode 170 may fill a space between the sidewalls of the lower electrode 330 having a cylinder shape. That is, at least a portion of the upper electrode 170 may be surrounded by the lower electrode 330.

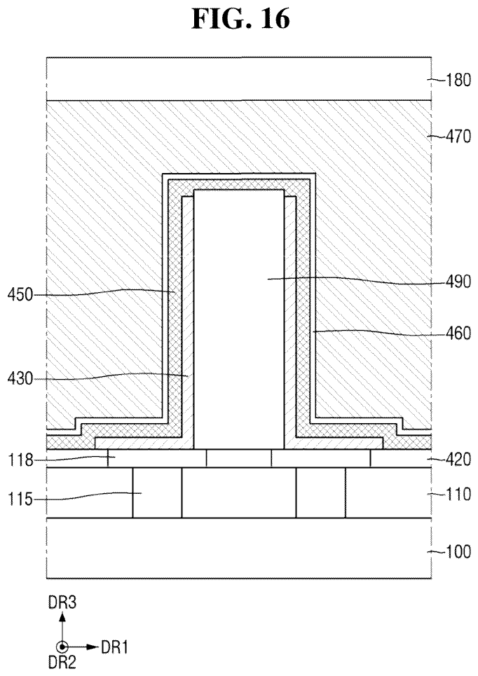

Hereinafter, a semiconductor device according to some other example embodiments of the inventive concepts will be described with reference to FIG. 16. The following description will be based on differences from the semiconductor device shown in FIGS. 1 and 2.

FIG. 16 is a view illustrating a semiconductor device according to some other example embodiments of the inventive concepts.

Referring to FIG. 16, the semiconductor device according to some other example embodiments of the inventive concepts may include an insulating pattern 490 disposed between two lower electrodes 430. The insulating pattern 490 may be extended in the second horizontal direction DR2.

A landing pad 118 may be disposed in an etch stop layer 420. The lower electrode 430 may be disposed on the landing pad 118. The lower electrode 430 may have an L-shape. For example, the lower electrode 430 may include a first portion extended in the first horizontal direction DR1 and a second portion extended in the vertical direction DR3. The first portion of the lower electrode 430 may be in contact with the landing pad 118. The second portion of the lower electrode 430 may be connected to one end of the first portion of the lower electrode 430.

The insulating pattern 490 may be disposed on sidewalls of the lower electrode 430. The insulating pattern 490 may be disposed on sidewalls of the second portion of the lower electrode 430. For example, the insulating pattern 490 may be disposed between the sidewalls of the second portion of the two lower electrodes 430. The insulating pattern 490 may be in contact with the sidewalls of the second portion of the lower electrode 430. The insulating pattern 490 may be extended in the vertical direction DR3 between the two lower electrodes 430.

A doping layer 450 may be disposed on an upper surface of the etch stop layer 420, a surface of the lower electrode 430 and an upper surface of the insulating pattern 490. For example, at least a portion of the doping layer 450 may be in contact with sidewalls of the insulating pattern 490 on an uppermost surface of the lower electrode 430. For example, an uppermost surface of the lower electrode 430 may be formed to be lower than the upper surface of the insulating pattern 490.

A capacitor dielectric layer 460 may be disposed on the doping layer 450. The capacitor dielectric layer 460 may be disposed along a surface of the doping layer 450. The capacitor dielectric layer 460 may be in contact with the doping layer 450. For example, the doping layer 450 may be disposed between the lower electrode 430 and the capacitor dielectric layer 460. The doping layer 450 may be disposed between the insulating pattern 490 and the capacitor dielectric layer 460. The doping layer 450 may be disposed between the etch stop layer 420 and the capacitor dielectric layer 460. For example, the capacitor dielectric layer 460 may be formed to be conformal. For example, the capacitor dielectric layer 460 is not disposed between the lower electrode 430 and the insulating pattern 490. The upper electrode 470 may be disposed on the capacitor dielectric layer 460.

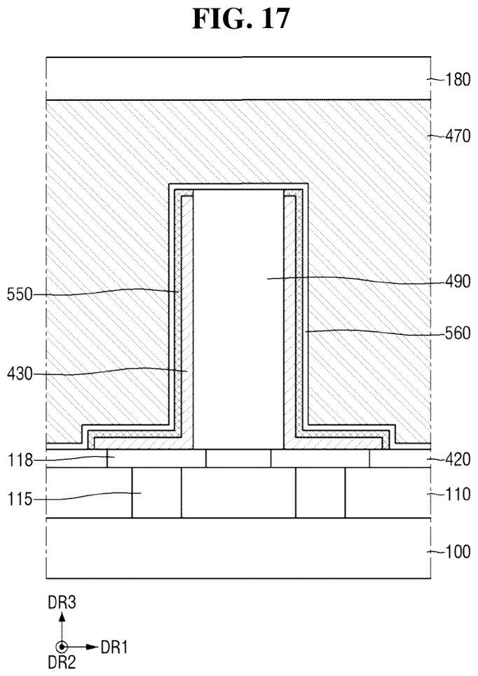

Hereinafter, a semiconductor device according to some other example embodiments of the inventive concepts will be described with reference to FIG. 17. The following description will be based on differences from the semiconductor device shown in FIG. 16.

FIG. 17 is a view illustrating a semiconductor device according to some other example embodiments of the inventive concepts.

Referring to FIG. 17, in the semiconductor device according to some example embodiments of the inventive concepts, a capacitor dielectric layer 560 may be in contact with a surface of the etch stop layer 420 and the upper surface of the insulating pattern 490.

For example, a doping layer 550 is not disposed on the upper surface of the insulating pattern 490. The capacitor dielectric layer 560 may be in contact with each of the upper surface of the etch stop layer 420 and the upper surface of the insulating pattern 490. For example, an uppermost surface of the doping layer 550 may be formed on the same plane as the upper surface of the insulating pattern 490.

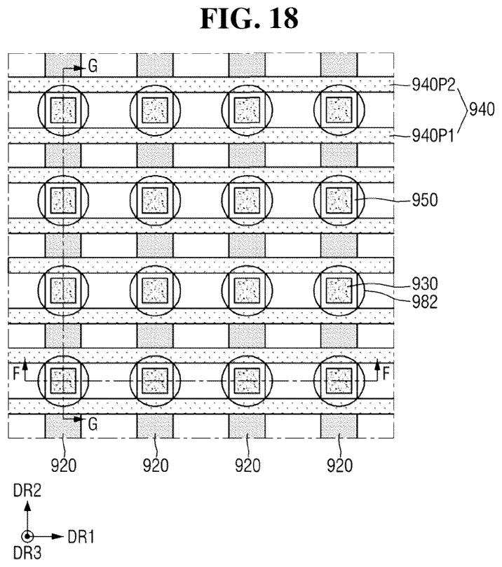

Hereinafter, a semiconductor device according to some other example embodiments of the inventive concepts will be described with reference to FIGS. 18 to 20.

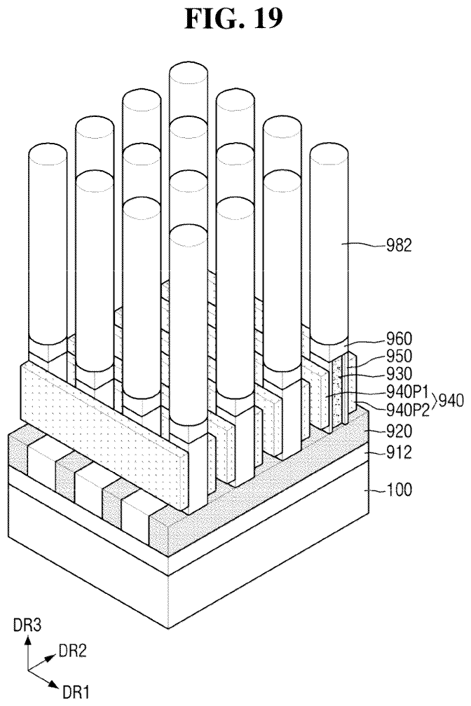

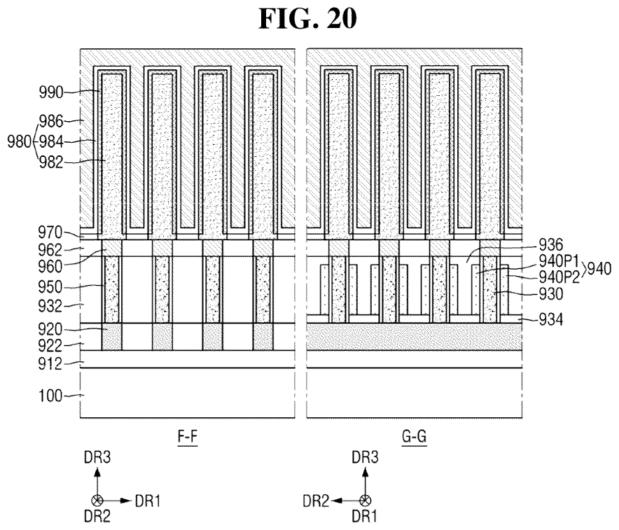

FIG. 18 is a layout view illustrating a semiconductor device according to some other example embodiments of the inventive concepts. FIG. 19 is a perspective view illustrating a semiconductor device according to some other example embodiments of the inventive concepts. FIG. 20 is a cross-sectional view taken along lines F-F and G-G of FIG. 18.

Referring to FIGS. 18 to 20, the semiconductor device according to some other example embodiments of the inventive concepts may include a substrate 100, a plurality of first conductive lines 920, a channel layer 930, a gate electrode 940, a gate insulating layer 950 and a capacitor 980. The semiconductor device according to some other example embodiments of the inventive concepts may include a vertical channel transistor (VCT). The vertical channel transistor may indicate a structure in which a channel length of the channel layer 930 is extended from the substrate 100 along the vertical direction DR3.

A lower insulating layer 912 may be disposed on the substrate 100. A plurality of first conductive lines 920 may be spaced apart from each other in the first horizontal direction DR1 on the lower insulating layer 912, and may be extended in the second horizontal direction DR2. A plurality of first insulating patterns 922 may be disposed on the lower insulating layer 912 to fill a space between the plurality of first conductive lines 920. The plurality of first insulating patterns 922 may be extended in the second horizontal direction DR2. An upper surface of the plurality of first insulating patterns 922 may be disposed at the same level as an upper surface of the plurality of first conductive lines 920. The plurality of first conductive lines 920 may serve as bit lines.

The plurality of first conductive lines 920 may include a doped semiconductor material, a metal, a conductive metal nitride, a conductive metal silicide, a conductive metal oxide or their combination. For example, the plurality of first conductive lines 920 may include, but are not limited to, doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx or their combination. The plurality of first conductive lines 920 may include a single layer or multiple layers of the aforementioned materials. In some example embodiments, the plurality of first conductive lines 920 may include graphene, a carbon nanotube or their combination.

The channel layer 930 may be disposed to be spaced apart from another one in the form of a matrix on the plurality of first conductive lines 920 in the first horizontal direction DR1 and the second horizontal direction DR2. The channel layer 930 may have a first width according to the first horizontal direction DR1 and a first height according to the vertical direction DR3, wherein the first height may be greater than the first width. In some example embodiments, the vertical direction DR3 crosses the first horizontal direction DR1 and the second horizontal direction DR2, and may be, for example, a direction perpendicular to the upper surface of the substrate 100. For example, the first height may be about 2 times to 10 times of the first width, but the inventive concepts are not limited thereto. A bottom portion of the channel layer 930 may serve as a first source/drain region (not shown), an upper portion of the channel layer 930 may serve as a second source/drain region (not shown), and a portion of the channel layer 930 between the first and second source/drain regions may serve as a channel region (not shown).

In some example embodiments, the channel layer 930 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn₂O, SnₓO, HfₓIn_{y}Zn₂O, GaₓZn_{y}Sn_{z}O, AlₓZn_{y}Sn_{z}O, YbₓGa_{y}Zn_{z}O, InₓGa_{y}O or their combination. The channel layer 930 may include a single layer or multiple layers of the oxide semiconductor. In some example embodiments, the channel layer 930 may have a bandgap energy that is greater than that of silicon. For example, the channel layer 930 may have a bandgap energy of about 1.5 eV to 5.6 cV. For example, the channel layer 930 may have optimal channel performance when the channel layer 930 has a bandgap energy of about 2.0 eV to 4.0 eV. For example, the channel layer 930 may be polycrystalline or amorphous, but is not limited thereto. In some example example embodiments, the channel layer 930 may include a graphene, a carbon nanotube or their combination.

The gate electrode 940 may be extended in the first horizontal direction DR1 on both sidewalls of the channel layer 930. The gate electrode 940 may include a first sub-gate electrode 940P1 facing a first sidewall of the channel layer 930 and a second sub-gate electrode 940P2 facing a second sidewall opposite to the first sidewall of the channel layer 930. As one channel layer 930 is disposed between the first sub-gate electrode 940P1 and the second sub-gate electrode 940P2, the semiconductor device may have a dual gate transistor structure, but the inventive concepts are not limited thereto. The second sub-gate electrode 940P2 may be omitted, and only the first sub-gate electrode 940P1 facing the first sidewall of the channel layer 930 may be formed so that a single gate transistor structure may be implemented. The gate electrode 940 may include a semiconductor material doped with impurities, a conductive silicide compound, a conductive metal nitride, a conductive metal oxide, a conductive metal oxynitride or a metal.

The gate insulating layer 950 may be interposed between the channel layer 930 and the gate electrode 940 while surrounding the sidewalls of the channel layer 930. For example, as shown in FIG. 18, the entire sidewalls of the channel layer 930 may be surrounded by the gate insulating layer 950, and a portion of sidewalls of the gate electrode 940 may be in contact with the gate insulating layer 950. In some other example embodiments, the gate insulating layer 950 may be extended in an extension direction (e.g., the first horizontal direction DR1) of the gate electrode 940, and only two sidewalls, which face the gate electrode 940, among the sidewalls of the channel layer 930 may be in contact with the gate insulating layer 950. In some example embodiments, the gate insulating layer 950 may be made of a silicon oxide layer, a silicon oxynitride layer, a high-k layer having a dielectric constant higher than that of the silicon oxide layer or their combination.

A plurality of second insulating patterns 932 may be extended along the second horizontal direction DR2 on the plurality of first insulating patterns 922, and the channel layer 930 may be disposed between two adjacent second insulating patterns 932 among the plurality of second insulating patterns 932. Also, a first buried layer 934 and a second buried layer 936 may be disposed in a space between two adjacent channel layers 930 between the two adjacent second insulating patterns 932. The first buried layer 934 may be disposed on a bottom portion of the space between the two adjacent channel layers 930, and the second buried layer 936 may be formed to fill the remainder of the space between the two adjacent channel layers 930 on the first buried layer 934. An upper surface of the second buried layer 936 may be disposed at the same level as that of the channel layer 930, and the second buried layer 936 may cover an upper surface of the gate electrode 940. Alternatively, the plurality of second insulating patterns 932 may be formed of a material layer continuous with the plurality of first insulating patterns 922, or the second buried layer 936 may be formed of a material layer continuous with the first buried layer 934.

A capacitor contact 960 may be disposed on the channel layer 930. The capacitor contact 960 may be disposed overlapping the channel layer 930 in the vertical direction DR3, and may be arranged in the form of a matrix to be spaced apart from another one in the first horizontal direction DR1 and the second horizontal direction DR2. The capacitor contact 960 may be made of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSIN, RuTiN, NiSi, CoSi, IrOx, RuOx or their combination, but the inventive concepts are not limited thereto. An upper insulating layer 962 may surround sidewalls of the capacitor contact 960 on the plurality of second insulating patterns 932 and the second buried layer 936.

An etch stop layer 970 may be disposed on the upper insulating layer 962, and a capacitor 980 may be disposed on the etch stop layer 970. The capacitor 980 may include a lower electrode 982, a doping layer 990, a capacitor dielectric layer 984, and an upper electrode 986. The lower electrode 982 may electrically be connected with an upper surface of the capacitor contact 960 through the etch stop layer 970. The lower electrode 982 may be formed of a pillar type extended in the vertical direction DR3, but the inventive concepts are not limited thereto. In some example embodiments, the lower electrode 982 may be disposed to overlap the capacitor contact 960 in the vertical direction DR3, and may be arranged in the form of a matrix spaced apart from another lower electrode in the first horizontal direction DR1 and the second horizontal direction DR2. Alternatively, a landing pad (not shown) may be further disposed between the capacitor contact 960 and the lower electrode 982, and the lower electrode 982 may be arranged in a hexagonal shape.

The doping layer 990 may be disposed between the lower electrode 982 and the capacitor dielectric layer 984. The doping layer 990 may include a metal oxide as a base material. For example, the doping layer 990 may include titanium oxide, tantalum oxide, iridium oxide, niobium oxide or ruthenium oxide as a base material. The doping layer 990 may include a first material, a second material and a third material, which are doped in the base material. The first material, the second material and the third material may be those different from one another.

For example, the first material may be a material having a trivalent atom valence electron. The first material may include at least one of, for example, aluminum (Al), gallium (Ga), indium (In), yttrium (Y), scandium (Sc) or lanthanum (La). The second material may be a material having a tetravalent atom valence electron. The second material may include at least one of zirconium (Zr), hafnium (Hf), silicon (Si), germanium (Ge) or tin (Sn). The third material may be a material having a pentavalent atom valence electron. The third material may include at least one of, for example, niobium (Nb), tantalum (Ta), vanadium (V), nitrogen (N), phosphorus (P), arsenic (As) or antimony (Sb).

For example, an atomic percent of the first material doped in the doping layer 990 may be about 0.1 at % to 10 at %. An atomic percent of the second material doped in the doping layer 990 may be about 1 at % to 30 at %. An atomic percent of the third material doped in the doping layer 990 may be about 0.1 at % to 10 at %. For example, the atomic percent of the first material doped in the doping layer 990 may be smaller than the atomic percent of the third material doped in the doping layer 990.

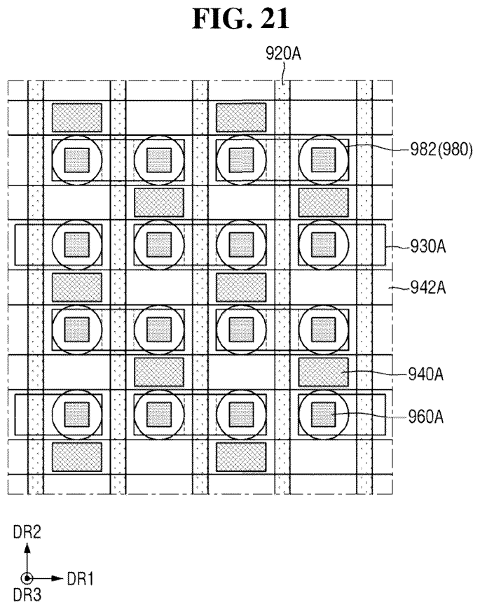

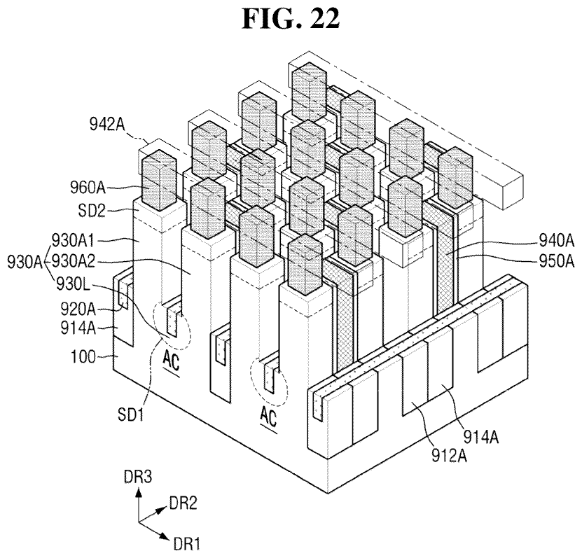

Hereinafter, a semiconductor device according to some other example embodiments of the inventive concepts will be described with reference to FIGS. 21 and 22.

FIG. 21 is a layout view illustrating a semiconductor device according to some other example embodiments of the inventive concepts. FIG. 22 is a perspective view illustrating a semiconductor device according to some other example embodiments of the inventive concepts.

Referring to FIGS. 21 and 22, the semiconductor device according to some other example embodiments of the inventive concepts may include a substrate 100, a plurality of first conductive lines 920A, a channel structure 930A, a contact gate electrode 940A, a plurality of second conductive lines 942A and a capacitor 980. The semiconductor device according to some other example embodiments of the inventive concepts may include a vertical channel transistor (VCT).

A plurality of active regions AC may be defined by a first device isolation pattern 912A and a second device isolation pattern 914A in the substrate 100. The channel structure 930A may be disposed inside each of the plurality of active regions AC. The channel structure 930A may include a first active pillar 930A1 and a second active pillar 930A2, which are extended in the vertical direction DR3, respectively, and a connection portion 930L connected with a bottom portion of the first active pillar 930A1 and a bottom portion of the second active pillar 930A2. A first source/drain region SD1 may be disposed in the connection portion 930L. A second source/drain region SD2 may be disposed above the first and second active pillars 930A1 and 930A2. Each of the first active pillar 930A1 and the second active pillar 930A2 may constitute an independent unit memory cell.

The plurality of first conductive lines 920A may be extended in a direction crossing each of the plurality of active regions AC, and may be extended in the second horizontal direction DR2, for example. One of the plurality of first conductive lines 920A may be disposed on the connection portion 930L between the first active pillar 930A1 and the second active pillar 930A2. One first conductive line 920A may be disposed on the first source/drain region SD1. Another first conductive line 920A adjacent to the above one first conductive line 920A may be disposed between two channel structures 930A. One of the plurality of first conductive lines 920A may serve as a common bit line included in two unit memory cells constituted by the first active pillar 930A1 and the second active pillar 930A2, which are disposed on both sides thereof.

One contact gate electrode 940A may be disposed between two channel structures 930A adjacent to each other in the second horizontal direction DR2. For example, the contact gate electrode 940A may be disposed between the first active pillar 930A1 included in one channel structure 930A and the second active pillar 930A2 of the channel structure 930A, which is adjacent to the first active pillar 930A1. One contact gate electrode 940A may be shared by the first active pillar 930A1 and the second active pillar 930A2, which are disposed on both sidewalls thereof. A gate insulating layer 950A may be disposed between the contact gate electrode 940A and the first active pillar 930A1 and between the contact gate electrode 940A and the second active pillar 930A2. The plurality of second conductive lines 942A may be extended in the first horizontal direction DR1 on an upper surface of the contact gate electrode 940A. The plurality of second conductive lines 942A may serve as word lines of the semiconductor device.

A capacitor contact 960A may be disposed on the channel structure 930A. The capacitor contact 960A may be disposed on the second source/drain region SD2, and a capacitor 980 may be disposed on the capacitor contact 960A. The capacitor 980 may include the lower electrode 982, the doping layer 990, the capacitor dielectric layer 984 and the upper electrode 986, which are shown in FIG. 20.

Although example embodiments of the inventive concepts have been described with reference to the accompanying drawings, it will be apparent to those skilled in the art that the inventive concepts can be fabricated in various forms without being limited to the above-described example embodiments and can be embodied in other specific forms without departing from technical spirit and essential characteristics of the inventive concepts. Thus, the above example embodiments are to be considered in all respects as illustrative and not restrictive.

What is claimed is:

1. A semiconductor device comprising:
a landing pad on a substrate;
a lower electrode extending in a vertical direction on the landing pad, the lower electrode connected to the landing pad;
a capacitor dielectric layer on the lower electrode;
a doping layer between the lower electrode and the capacitor dielectric layer, the doping layer in contact with each of the lower electrode and the capacitor dielectric layer, the doping layer doped with first to third materials,
the first material having a trivalent atom valence electron, the second material having a tetravalent atom valence electron, and the third material having a pentavalent atom valence electron; and
an upper electrode on the capacitor dielectric layer.

2. The semiconductor device of claim 1, wherein an atomic percent of the first material doped in the doping layer is smaller than an atomic percent of the third material doped in the doping layer.

3. The semiconductor device of claim 1, wherein an atomic percent of the first material doped in the doping layer is 0.1 at % to 10 at %, an atomic percent of the second material doped in the doping layer is 1 at % to 30 at %, and an atomic percent of the third material doped in the doping layer is 0.1 at % to 10 at %.

4. The semiconductor device of claim 1, further comprising a supporter pattern on at least one side of the lower electrode, the supporter pattern in contact with sidewalls of the lower electrode,
wherein at least a portion of the doping layer is in contact with sidewalls of the supporter pattern on an upper surface of the lower electrode.

5. The semiconductor device of claim 4, wherein at least another portion of the doping layer is on an upper surface of the supporter pattern.

6. The semiconductor device of claim 5, wherein the doping layer on the upper surface of the lower electrode has a first thickness in the vertical direction, the another portion of the doping layer on the upper surface of the supporter pattern has a second thickness in the vertical direction, and the first thickness is greater than the second thickness.

7. The semiconductor device of claim 4, wherein the capacitor dielectric layer is in contact with an upper surface of the supporter pattern.

8. The semiconductor device of claim 4, wherein an uppermost surface of the doping layer is coplanar with an upper surface of the supporter pattern.

9. The semiconductor device of claim 1, wherein at least a portion of the upper electrode is surrounded by the lower electrode.

10. The semiconductor device of claim 1, further comprising an insulating pattern on sidewalls of the lower electrode, the insulating pattern in contact with the sidewalls of the lower electrode, the insulating pattern extending in the vertical direction,
wherein the lower electrode has an L-shape, and
wherein at least a portion of the doping layer is in contact with sidewalls of the insulating pattern on an uppermost surface of the lower electrode.

11. The semiconductor device of claim 10, wherein at least a portion of the doping layer is on an upper surface of the insulating pattern.

12. The semiconductor device of claim 10, wherein the capacitor dielectric layer is in contact with an upper surface of the insulating pattern.

13. A semiconductor device comprising:
a landing pad on a substrate;
a lower electrode extending in a vertical direction on the landing pad, the lower electrode connected to the landing pad;
a first supporter pattern on at least one side of the lower electrode, the first supporter pattern in contact with sidewalls of the lower electrode;
a second supporter pattern on at least one side of the lower electrode, the second supporter pattern in contact with the sidewalls of the lower electrode, the second supporter pattern spaced apart from the first supporter pattern in the vertical direction;
a capacitor dielectric layer on the lower electrode and the second supporter pattern; and
a doping layer between the lower electrode and the capacitor dielectric layer, the doping layer in contact with each of the lower electrode and the capacitor dielectric layer, the doping layer doped with first to third materials,
the first material having a trivalent atom valence electron, the second material having a tetravalent atom valence electron, and the third material having a pentavalent atom valence electron,
wherein at least a portion of the doping layer is in contact with sidewalls of the second supporter pattern on an upper surface of the lower electrode.

14. The semiconductor device of claim 13, wherein an atomic percent of the first material doped in the doping layer is smaller than an atomic percent of the third material doped in the doping layer.

15. The semiconductor device of claim 13, wherein at least a portion of the doping layer overlaps the lower electrode in the vertical direction between the first supporter pattern and the second supporter pattern.

16. The semiconductor device of claim 13, wherein at least a portion of the doping layer is on an upper surface of the second supporter pattern.

17. The semiconductor device of claim 16, wherein the doping layer on the upper surface of the lower electrode has a first thickness in the vertical direction, the at least a portion of the doping layer on the upper surface of the second supporter pattern has a second thickness in the vertical direction, and the first thickness is greater than the second thickness.

18. The semiconductor device of claim 13, wherein the capacitor dielectric layer is in contact with an upper surface of the second supporter pattern.

19. The semiconductor device of claim 13, wherein an uppermost surface of the doping layer is coplanar with an upper surface of the second supporter pattern.

20. A semiconductor device comprising:
a landing pad on a substrate;
a lower electrode extending in a vertical direction on the landing pad, the lower electrode connected to the landing pad;
a first supporter pattern on at least one side of the lower electrode, the first supporter pattern in contact with sidewalls of the lower electrode;
a second supporter pattern on at least one side of the lower electrode, the second supporter pattern in contact with the sidewalls of the lower electrode, the second supporter pattern spaced apart from the first supporter pattern in the vertical direction;
a capacitor dielectric layer on the lower electrode and the second supporter pattern;
a doping layer between the lower electrode and the capacitor dielectric layer and between an upper surface of the second supporter pattern and the capacitor dielectric layer, the doping layer in contact with each of the lower electrode, the capacitor dielectric layer and the upper surface of the second supporter pattern, the doping layer doped with first to third materials,
the first material having a trivalent atom valence electron, the second material having a tetravalent atom valence electron, and the third material having a pentavalent atom valence electron; and
an upper electrode on the capacitor dielectric layer,
wherein at least a portion of the doping layer is in contact with sidewalls of the second supporter pattern on an upper surface of the lower electrode,
wherein an atomic percent of the first material doped in the doping layer is smaller than an atomic percent of the third material doped in the doping layer, and
wherein the doping layer on the upper surface of the lower electrode has a first thickness in the vertical direction, the doping layer on the upper surface of the second supporter pattern has a second thickness in the vertical direction, and the first thickness is greater than the second thickness.
